(19) United States
(12) Patent Application Publication
(10) Pub. No.: US 2006/0191556 A1
(43) Pub. Date: Aug. 31, 2006

(54) Substrate processing apparatus and substrate processing method

(75) Inventors: Yoshiyuki Nakazawa, Kyoto (JP); Sadao Hirae, Kyoto (JP); Takamasa Sakai, Kyoto (JP)

Correspondence Address: OSTROLENK FABER GERB & SOFFEN, 1180 AVENUE OF THE AMERICAS, NEW YORK, NY, 100368403, US

(73) Assignee: DAINIPPON SCREEN MFG. CO., LTD.

(21) Appl. No.: 11/360,891

(22) Filed: Feb. 23, 2006

(30) Foreign Application Priority Data
Feb. 28, 2005 (JP) JP2005-054189

(51) Int. Cl. C23G 1/00; H01L 21/306

(52) U.S. Cl. 134/2; 156/345.23

(57) ABSTRACT

In a substrate processing apparatus (1), a ring-shaped cover part (61) opposed to an annular surface (51a) of a rotating part (51) is provided and the rotating part (51) rotates the substrate (9) while holding the substrate (9). An exhaust flow space (64) connecting with a gap space (62) between the cover part (61) and the annular surface (51a) along an outer edge of the cover part (61) is formed by a duct main body (63) connected to the cover part (61) along the outer edge of the cover part (61). Since a cross-sectional area of the exhaust flow space (64) increases gradually along a rotation direction of the rotating part (51), it is possible to reduce variation of inlet flow speed of air around the gap space (62) and to suppress nonuniformity of processing of the substrate (9).

### BACKGROUND OF THE INVENTION

1. Field of the Invention

The present invention relates to a technique for processing a substrate.

2. Description of the Background Art

A substrate processing apparatus which processes a substrate by rotating a semiconductor substrate or a glass substrate (hereinafter, referred to as “substrate”) and supplying the substrate with various processing solutions has been conventionally used. For example, a thin substrate processing apparatus has been suggested, which comprises a ring-shaped motor with a ring-shaped stationary part and a ring-shaped rotating part, and processes a substrate while rotating the substrate together with the rotating part which is a holding part (such substrate processing apparatus is referred to, for example, in Japanese Patent Application Laid Open Gazette No. 2003-111352 (Document 1)).

A substrate processing apparatus shown in Japanese Patent Application Laid Open Gazette No. 2000-150452 discloses a technique for increasing exhaust efficiency in an exhaust cup of the apparatus. In the apparatus, a substrate holding part is disposed within the exhaust cup, exhaust openings are formed at the bottom of the exhaust cup and on the internal side surface of the exhaust cup, covers are formed along a rotation direction of the substrate with tilting downward to cover the exhaust openings in a lower part of the exhaust cup, respectively. Japanese Patent Application Laid Open Gazette No. 10-151401 discloses a technique for improving exhausting ability of a substrate processing apparatus, where an exhaust cup connects to a first exhausting path, a substrate holding part is disposed within the exhaust cup and around the exhaust cup, an annular opening part connecting to a second exhausting path is further provided.

Meanwhile, size of substrate is increasing recently, however, in a larger size substrate, uniformity of processing is getting worse. To achieve uniform processing over the entire main surface of a substrate in cleaning, drying, or the like, it is necessary to exhaust gas from an outer edge of the substrate almost uniformly in a substrate processing apparatus. In the process of supplying processing solution to the substrate, it is extremely important to remove (drain) processing solution from the center of the substrate approximately radially and uniformly with exhausting gas uniformly. In a large size substrate, however, in the case where gas is exhausted from an exhaust opening(s) formed at the bottom of the cup, uniformity of exhausting in a circumferential direction comes down. If a cup is provided in an apparatus for processing a large size substrate, the size of the apparatus increases in a horizontal direction and downward. In particular, in a case where a cup is provided in an apparatus having the ring-shaped motor described in Document 1, it is difficult to downsize the apparatus even if the ring-shaped motor is used.

### SUMMARY OF THE INVENTION

The present invention is intended for a substrate processing apparatus for processing a substrate. It is an object of the present invention to reduce variation of exhaust speed around an outer edge of a substrate and to suppress nonuniformity of processing of the substrate.

The substrate processing apparatus comprises a holding part for holding a substrate; a rotation mechanism for rotating the holding part around a predetermined central axis perpendicular to a main surface of a substrate held by the holding part; a ring-shaped cover part opposed to an annular zone on an outer part of a rotating body which includes the holding part and a substrate rotated by the rotation mechanism, the annular zone being perpendicular to the central axis with a center of the annular zone lying on the central axis; and a member forming an exhaust flow space which connects with a gap space between the cover part and the annular zone along an outer edge of the cover part, a cross-sectional area of the exhaust flow space increasing along a rotation direction of the holding part.

According to the present invention, in the substrate processing apparatus, it is possible to reduce variation of inlet flow speed of gas around the gap space between the cover part and the annular zone on the rotating body and to suppress nonuniformity of processing of a substrate.

Normally, an outer part of the holding part is located outside a substrate held by the holding part and the annular zone lies on the holding part. Preferably, the holding part is a part of a ring-shaped rotating part combined with a ring-shaped stationary part in a ring-shaped motor, and the rotation mechanism is a driving mechanism of the motor. This makes it possible to downsize the substrate processing apparatus.

According to a preferred embodiment of the present invention, a guiding mechanism, for guiding rotation of the ring-shaped rotating part relative to the ring-shaped stationary part, comprises a supplying channel for supplying gas to a clearance between the ring-shaped stationary part and the ring-shaped rotating part, an auxiliary channel for exhausting gas ejected from the clearance between the ring-shaped stationary part and the ring-shaped rotating part is provided parallel to the exhaust flow space along an outer edge of the motor, and the exhaust flow space and the auxiliary channel are formed by partitioning a duct provided along the outer edge of the motor. It is therefore possible to provide the exhaust flow space and the auxiliary channel in the apparatus with simple structure.

According to an aspect of the present invention, a cross-sectional area of the exhaust flow space at a point on an outer edge of the rotating body is proportional to a distance from a starting point of the exhaust flow space to the point on the outer edge along the outer edge in the rotation direction of the holding part. This makes it possible to further reduce variation of inlet flow speed of gas around the gap space between the cover part and the annular zone on the rotating body.

According to another aspect of the present invention, since a width and a height of the exhaust flow space increase gradually along the rotation direction of the holding part, it is possible to exhaust gas efficiently in the exhaust flow space.

The present invention is also intended for a substrate processing method for processing a substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a construction of a substrate processing apparatus;

FIG. 2 is a plan view showing a rotating part and an exhaust part;

FIGS. 3A to 3D are respectively cross-sectional views of the exhaust part at the positions indicated by the arrows I-I, II-II, III-III, and IV-IV of FIG. 2;

FIG. 4 is an operation flow of the substrate processing apparatus for cleaning a substrate;

FIG. 5 is a view for schematically explaining inlet flow speed of air;

FIG. 6 is a view showing another example of an exhaust part;

FIGS. 7A to 7C are respectively cross-sectional views of the exhaust part at the positions indicated by the arrows V-V, VI-VI, and VII-VII of FIG. 6;

FIG. 8 is a view showing still another example of an exhaust part; and

FIG. 9 is a view showing another example of a substrate processing apparatus.

### DESCRIPTION OF THE PREFERRED EMBODIMENTS

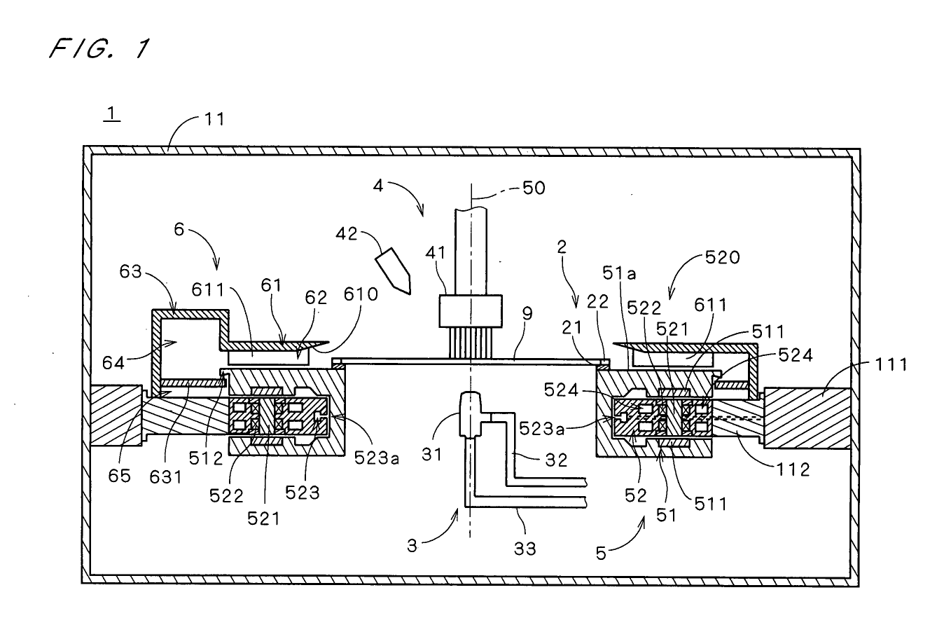

FIG. 1 is a view showing a construction of a substrate processing apparatus 1 in accordance with a preferred embodiment of the present invention. The substrate processing apparatus 1 in the preferred embodiment is an apparatus for cleaning both main surfaces of a semiconductor substrate 9 (hereinafter, referred to as “substrate 9”) to remove foreign substances such as unwanted particles or the like adhering to the substrate 9.

As shown in FIG. 1, the substrate processing apparatus 1 comprises a substrate holding mechanism 2 for holding an outer part of the disk-shaped substrate 9, a first cleaning mechanism 3 which is located below a lower surface, that is one main surface, of the substrate 9 held by the substrate holding mechanism 2 and performs dry physical cleaning to the lower surface of the substrate 9, and a second cleaning mechanism 4 which is located above an upper surface of the substrate 9 and performs wet cleaning using liquid to the upper surface, that is the other main surface, of the substrate 9. The dry physical cleaning is a dry cleaning technique for cleaning the substrate 9 without supplying liquid (hereinafter, referred to as “cleaning solution”) onto the substrate 9, where no chemical reaction is used.

The substrate holding mechanism 2 has a holding ring 21 contacting with the outer part of the substrate 9 from the lower side and holding pins 22 slightly moving their tips to/from a side surface of the substrate 9 on the holding ring 21.

The substrate processing apparatus 1 further comprises an approximately ring-shaped motor 5 which rotates the substrate 9 in a plane parallel to the lower and upper surfaces of the substrate 9 by rotating the substrate holding mechanism 2. In an outer part of the motor 5, provided is an exhaust part 6 which collects (drains) used cleaning solution (which is cleaning solution supplied in cleaning of the upper surface of the substrate 9 and it is hereinafter referred to as “cleaning drainage”) from the outside of the substrate 9 in the wet cleaning by the second cleaning mechanism 4 and exhausts gas. As simply shown in FIG. 1, the substrate processing apparatus 1 comprises a chamber 11 housing the substrate holding mechanism 2, the first cleaning mechanism 3, the second cleaning mechanism 4, the motor 5, and the exhaust part 6. It is not necessary to provide the chamber 11 as a sealed housing structure.

In the preferred embodiment, the substrate 9 is held with a front side surface, on which a fine pattern is formed, turning down and with a back side surface turning up. In the following description, the upper surface of the substrate 9 is the back side surface of the substrate 9 and the lower surface is the front side surface of the substrate 9.

The second cleaning mechanism 4 comprises a cleaning solution supplying part 42 for supplying the cleaning solution onto the upper surface of the substrate 9 and a cleaning brush 41 which contacts with the upper surface of the substrate 9 where the cleaning solution is supplied, and the cleaning brush 41 cleans the upper surface by brushing. In the substrate processing apparatus 1, since the upper surface of the substrate 9 is spatially isolated from the lower surface by the substrate holding mechanism 2, the cleaning solution supplied onto the upper surface of the substrate 9 is prevented from flowing onto the lower surface of the substrate 9.

The first cleaning mechanism 3 comprises an ejection nozzle 31 serving as a particle ejection mechanism for ejecting carbon dioxide (CO₂) particles toward the lower surface of the substrate 9, and a nitrogen gas supply pipe 32 and a carbon dioxide supply pipe 33 for supplying nitrogen (N₂) gas and liquid carbon dioxide to the ejection nozzle 31, separately. A liquid outlet for ejecting liquid carbon dioxide is formed at a top end of the ejection nozzle 31 and a gas outlet for ejecting nitrogen gas is formed around the liquid outlet. By supplying liquid carbon dioxide and nitrogen gas to the ejection nozzle 31, the liquid carbon dioxide is ejected from the liquid outlet of the ejection nozzle 31 and the nitrogen gas is strongly ejected from the gas outlet. Carbon dioxide particles (dry ice particles) frozen by adiabatic expansion in ejecting are mixed with a stream of the nitrogen gas which is career gas, and accelerated. The ejection nozzle 31 is a so-called two fluid nozzle with external mixing. Solid carbon dioxide particles carried by carrier gas collide with the substrate 9 while spreading, and as a result, unwanted fine particles such as organic matter are efficiently removed from the lower surface of the substrate 9. In the ejection nozzle 31, since the liquid carbon dioxide and the nitrogen gas are directed upward along respective channels of nozzle, directivity of ejection of the carbon dioxide particles from the ejection nozzle 31 goes up, and the carbon dioxide particles are efficiently ejected to the substrate 9.

The motor 5 is a hollow motor having a hollow portion inside thereof. The motor 5 comprises an approximately ring-shaped rotating part 51 which rotates around a central axis 50 extending in a vertical direction and is provided along the outer part of the substrate 9, and an approximately ring-shaped stationary part 52 which is combined with the rotating part 51 and generates a torque with the rotating part 51. An upper surface of the rotating part 51 has an annular shape (hereinafter, the surface is referred to as “annular surface 51a”). The substrate holding mechanism 2 is installed in an upper part of the rotating part 51 and serves as a part of the rotating part 51. The outer part of the substrate 9 is located above the annular surface 51 a and a central axis of the substrate 9 which is perpendicular to both the main surfaces of the substrate 9 coincides with the central axis 50.

The rotating part 51 is combined with the stationary part 52 so that an internal side surface (i.e., a side surface opposed to the central axis 50), an upper surface, and a lower surface of the stationary part 52 are covered with the rotating part 51, and the rotating part 51 comprises two conductive plates 511 opposed to the upper and lower surfaces of the stationary part 52, respectively. The stationary part 52 comprises a lot of magnetic cores 521 which are disposed almost circularly around the central axis 50 with predetermined gaps between adjacent magnetic cores 521 and coils 522 each of which are provided on a few magnetic cores 521. The magnetic cores 521 and the coils 522 are opposed to the conductive plates 511 to form an armature 520. Each of the magnetic cores 521 is formed by many flat rolled silicon steel chips which are layered one on another. Each of the coils 522 is formed by winding a enameled wire around the magnetic cores 521.

Inside the stationary part 52, formed are an annular gas channel 523 through which gas (nitrogen gas in the preferred embodiment) flows and a plurality of annular cooling water channels 524 through which cooling water flows. In the gas channel 523, a lot of minute openings 523a for supplying gas to a fine clearance between the internal side surface of the stationary part 52 and the rotating part 51 are formed. Gas supplied from an external gas supply apparatus to the gas channel 523 is ejected from the openings 523a, and the stationary part 52 and the rotating part 51 are kept slightly away from each other. The rotating part 51 is supported by the stationary part 52 through gas, to form a mechanism of a static pressure gaseous bearing. The stationary part 52 is fitted into a ring-shaped member 112 and is supported from an outer side thereof. The stationary part 52 is fixed to an inner wall of the chamber 11 through a motor supporting part 111. In a state where the substrate 9 is held by the substrate holding mechanism 2, an internal space of the chamber 11 is divided into an upper part and a lower part of the substrate 9 by the substrate 9, the substrate holding mechanism 2, the motor 5, the ring-shaped member 112, and the motor supporting part 111.

In the motor 5, multiphase alternating current (two-phase alternating current or three-phase alternating current, for example) is sequentially given to a plurality of coils 522, and traveling magnetic fields are generated on the upper surface and the lower surface of the stationary part 52 along the armature 520. As a result, eddy currents are produced in the conductive plates 511 of the rotating part 51 provided above and under the armature 520, and a torque is given to the rotating part 51 according to the dynamics of a linear motor. In the motor 5, the armature 520 and the conductive plates 511 serve as a driving mechanism of the motor 5. As described above, gas is supplied to the clearance between the internal side surface of the stationary part 52 and the rotating part 51 by the gas channel 523, to guide rotation of the rotating part 51 relative to the stationary part 52. The rotating part 51, the substrate holding mechanism 2 and the substrate 9 smoothly rotate as one rotating body around the central axis 50 perpendicular to the main surface of the substrate 9. In the stationary part 52, cooling water is supplied from an external cooling water supply apparatus to the cooling water channels 524, and then heat generated in the plurality of coils 522 is removed.

As shown in FIG. 1, the exhaust part 6 has a concentric ring-shaped cover part 61 positioned above the annular surface 51a of the rotating part 51. An inner side surface of the cover part 61 is an inclined surface 610 whose diameter gradually increases toward lower portion thereof. A gap space 62 is formed between the cover part 61 and the annular surface 51a and has a constant height (width) across the whole outer edge of the cover part 61. In FIG. 1, the width of the gap space 62 is shown wider than it is. A duct main body 63 is provided outside the cover part 61 and connects with an outer part of the cover part 61 to cover the ring-shaped member 112. The duct main body 63 bends downward at an outer part thereof and contacts with an outer part of the ring-shaped member 112. A duct, which is a space for exhausting gas and draining cleaning drainage in cleaning the substrate 9, is formed along an outer edge of the motor 5 by the duct main body 63 and the ring-shaped member 112.

Inside the duct main body 63, a ring-shaped partition plate 631 projecting out toward the rotating part 51 is attached. At an upper part of the rotating part 51, a ring-shaped projecting part 512 projecting out to the outside is formed. An inner part of the partition plate 631 and the projecting part 512 overlap each other to form a labyrinth structure, and the duct is partitioned into an upper part and a lower part. Therefore, in the duct, an exhaust flow space 64 of the upper part connecting with the gap space 62 along the outer edge of the cover part 61 and an auxiliary channel 65 of the lower part provided parallel to the exhaust flow space 64 along the outer edge of the motor 5 are formed with simple structure. The auxiliary channel 65 is used for exhausting gas ejected from the upper clearance between the stationary part 52 and the rotating part 51 of the motor 5. The partition plate 631 and the projecting part 512 prevent cleaning drainage and air drained (or exhausted) to the exhaust flow space 64 from flowing into the motor 5 in cleaning discussed later.

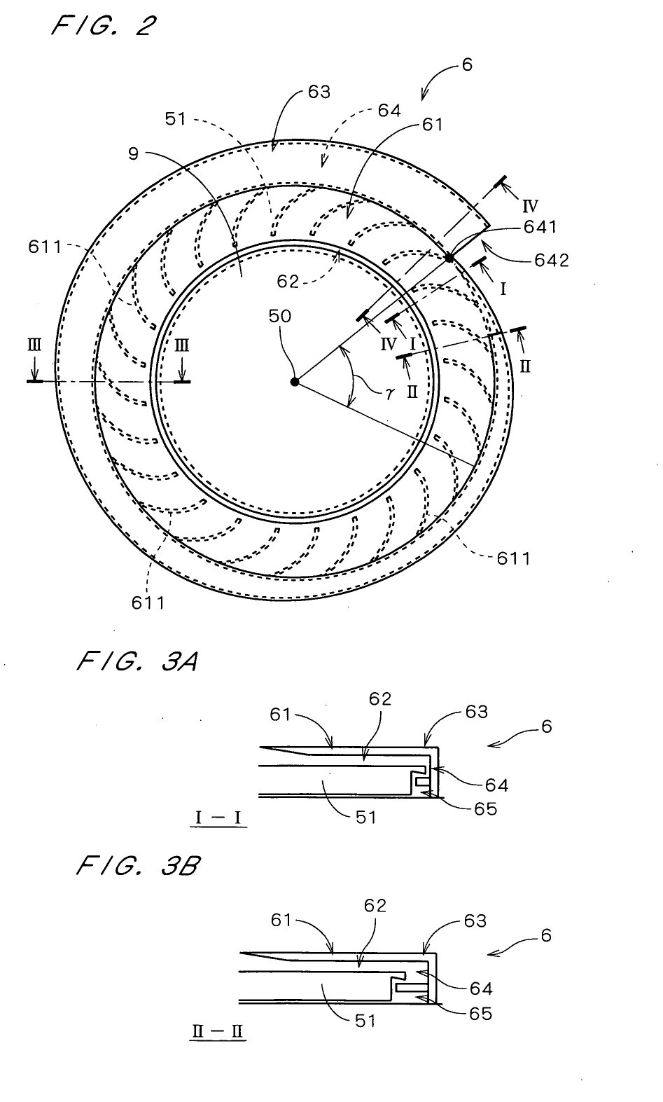

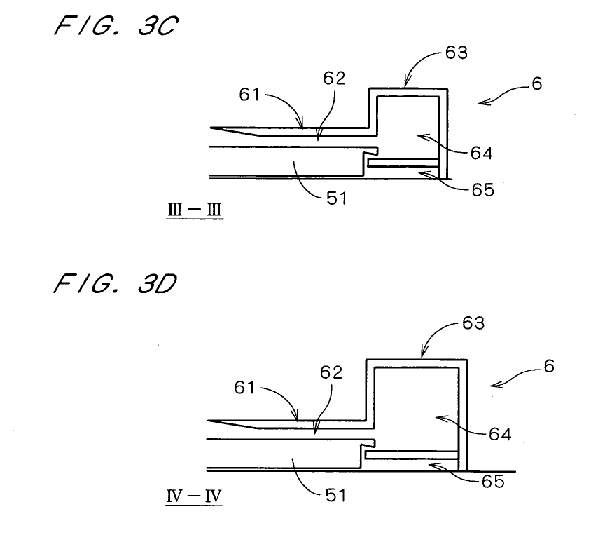

FIG. 2 is a plan view showing the rotating part 51 and the exhaust part 6. FIGS. 3A to 3D are respectively cross-sectional views at the positions indicated by the arrows I-I, II-II, III-III, and IV-IV of FIG. 2. In FIGS. 3A to 3D, hatching of cross sections are omitted.

As shown in FIG. 2, width of the duct main body 63 in a radial direction (i.e., direction departing from the central axis 50) increases gradually from a starting point 641 of the exhaust flow space 64 along a rotation direction (clockwise direction in FIG. 2) of the rotating part 51. The width becomes maximum at a point just before the starting point 641, and at the point, an opening 642 which is an ending point of the whorl-like exhaust flow space 64 is provided.

Specifically, the width of the exhaust flow space 64 in the radial direction is very narrow at the position indicated by the arrows I-I in the immediate downstream vicinity of the starting point 641 in the rotation direction of the rotating part 51, as shown in FIG. 3A. Only in the radial direction, the width of the exhaust flow space 64 increases gradually from the position indicated by the arrows I-I toward the downstream side of the rotation direction. At the position indicated by the arrows II-II, a cross section of the exhaust flow space 64 is almost square as shown in FIG. 3B. The width and height of the exhaust flow space 64 increase gradually from the position indicated by the arrows II-II along the rotation direction at the same rate. At the position indicated by the arrows III-III, a nearly square cross section of the exhaust flow space 64 is larger than the cross section in FIG. 3B, as shown in FIG. 3C. At the position indicated by the arrows IV-IV in the immediate upstream vicinity of the opening 642 in the rotation direction, the nearly square cross section of the exhaust flow space 64 becomes larger than that in FIG. 3C, as shown in FIG. 3D. More accurately, in the downstream side of the rotation direction from the position indicated by the arrows II-II, a cross-sectional area of the exhaust flow space 64 increases gradually along the rotation direction so that a cross-sectional area of the exhaust flow space 64 at a point on the outer edge of the rotating part 51 is proportional to a distance from the starting point 641 of the exhaust flow space 64 to the point on the outer edge of the rotating part 51 along the outer edge in the rotation direction. Also, the cross section of the exhaust flow space 64 is nearly square (i.e., cross section is nearly square in almost whole exhaust flow space 64). Actually, in the opening 642 (and an opening of the auxiliary channel 65), an exhaust pipe (not shown) having a enough large cross-sectional area in comparison with an area of the opening 642 is provided, and cleaning drainage and air drained through the exhaust flow space 64 is collected by the exhaust pipe.

As shown in FIGS. 3A to 3D, a width of the auxiliary channel 65 increases gradually in the same way with the exhaust flow space 64 and a cross-sectional area of the auxiliary channel 65 also increases gradually along the rotation direction. In the cover part 61, a plurality of rectifying plates 611 which project out from a surface opposed to the rotating part 51 toward the rotating part 51 (see FIG. 1) and extend from the central axis 50 side toward the outer edge of the rotating part 51 with inclining in the rotation direction are provided radially as shown in FIG. 2. The cross-sectional view of FIG. 1 shows the entire rectifying plates 611. In FIGS. 3A to 3D, the rectifying plates 611 are omitted.

Next discussion will be made on an operation flow of the substrate processing apparatus 1 for cleaning a substrate 9 referring to FIG. 4. When cleaning is performed by the substrate processing apparatus 1 of FIG. 1, first, the substrate 9 is loaded in the chamber 11 and is held by the substrate holding mechanism 2 (Step S11). The upper surface of the substrate 9 is located between the cover part 61 and the annular surface 51a with respect to the central axis 50 direction. Since an inner diameter of the cover part 61 is larger than an outer diameter of the substrate 9, the substrate 9 can be placed on the rotating part 51 easily (same as in unloading the substrate 9 which is later discussed). Subsequently, the motor 5 starts rotating the substrate 9 (Step S12), and ejection of carbon dioxide particles to the lower surface of the substrate 9 and swing of the ejection nozzle 31 are started by the first cleaning mechanism 3 (Step S13). In the first cleaning mechanism 3, the ejection nozzle 31 moves repeatedly between the center and the outer edge of the substrate 9 under the substrate 9 while continuing to eject carbon dioxide particles, and then dry physical cleaning to the lower surface of the substrate 9 (i.e., the front side surface of the substrate 9) is performed.

In the second cleaning mechanism 4, simultaneously with cleaning of the lower surface of the substrate 9 by the first cleaning mechanism 3, supplying cleaning solution onto the upper surface of the substrate 9 by the cleaning solution supplying part 42 and rubbing the upper surface by the cleaning brush 41 are started (Step S14). In parallel with cleaning the lower surface of the substrate 9 by the first cleaning mechanism 3, the cleaning brush 41 moves repeatedly between the center and the outer edge of the substrate 9 above the substrate 9 while continuing to clean the upper surface of the substrate 9 by brushing, and then wet cleaning to the upper surface of the substrate 9 (i.e., the back side surface of the substrate 9) is performed.

While cleaning of the upper surface of the substrate 9 is performed, removing cleaning drainage from the upper surface of the substrate 9 is performed in the substrate processing apparatus 1. Specifically, by rotation of the substrate 9 and the rotating part 51, cleaning drainage on the upper surface of the substrate 9 moves to the outer edge of the substrate 9 by the centrifugal force, and the cleaning drainage flows into the gap space 62 between the cover part 61 and the annular surface 51a. Since the inner side surface of the cover part 61 is the inclined surface 610, the cleaning drainage flows into the gap space 62 efficiently. The cleaning drainage flowing into the gap space 62 flows out to the exhaust flow space 64. In the following description, with imaging a ring-shaped imaginary member filling the gap space 62 between the ring-shaped cover part 61 and the annular surface 51a, a cross-section corresponding to an internal side surface of the imaginary member is referred to as an inlet cross-section and a cross-section corresponding to an external side surface is referred to as an outlet cross-section.

Air on the substrate 9 and the rotating part 51 moves to the outside by the centrifugal force while being drugged with a movement of the surface of the substrate 9 and a flow of cleaning solution, and flows into the gap space 62 from the inlet cross-section. And the air is guided to the outside by the rectifying plates 611 smoothly, it flows out to the exhaust flow space 64 from the outlet cross-section, and is collected (Step S15). With this operation, in a space above the substrate 9, air blown onto the central area of the substrate 9 flows to the outer edge of the substrate 9 along the upper surface of the substrate 9 and it is sucked into the gap space 62.

Regarding air exhausted through the gap space 62, since the cross-sectional area of the exhaust flow space 64 of FIG. 2 linearly increases from the starting point 641 along the rotation direction, an amount (volume) of air per unit area of the outlet cross-section which flows out from the gap space 62 to the exhaust flow space 64 during a unit time is almost constant from the starting point 641 to the opening 642 of the ending point along the rotation direction. An amount of air per unit area of the inlet cross-section which is sucked from the space above the substrate 9 into the gap space 62 is therefore almost constant. In other words, inlet flow speed of air around the gap space 62 is almost constant across the whole inlet cross-section along the rotation direction. Therefore, effects of air flow in draining the cleaning drainage from the substrate 9 are also uniformed in a circumferential direction. Actually, although flow of air and cleaning drainage into the gap space 62 is affected by the cleaning brush 41 or the like, in all the cleaning process, draining liquid is nearly uniformed across the whole inlet cross-section and cleaning process of the upper surface of the substrate 9 using cleaning solution is performed appropriately.

Since the outer part of the substrate 9 is held by the substrate holding mechanism 2 and the cover part 61 is opposed to only the outer part of the annular surface 51 a located outside the substrate 9 (i.e., the cover part 61 is not opposed to the substrate 9), almost whole the upper and lower surfaces of the substrate 9 can be cleaned simultaneously and easily. Further, by making carbon dioxide particles from the ejection nozzle 31 collide with the lower surface of the substrate 9, it is possible to remove unwanted adhering particles efficiently without damaging the fine pattern formed on the lower surface of the substrate 9. In parallel with the dry physical cleaning to the lower surface of the substrate 9, the effective wet cleaning is performed to the upper surface of the substrate 9 by rubbing with the cleaning brush 41, it is therefore possible to remove foreign substances firmly adhering to the upper surface efficiently.

After cleaning of the upper and lower surfaces of the substrate 9 is finished, ejection of carbon dioxide particles by the ejection nozzle 31, supply of cleaning solution by the cleaning solution supplying part 42, and rubbing of the substrate 9 by the cleaning brush 41 are stopped, and the ejection nozzle 31 and the cleaning brush 41 move outside the substrate 9.

In the substrate processing apparatus 1, further, by continuing to rotate the substrate 9, the upper and lower surfaces of the substrate 9 are dried (Step S16). Also in this case, since inlet flow speed of air around the gap space 62 is almost constant across the whole inlet cross-section, cleaning solution is removed from the upper surface of the substrate 9 uniformly and rapidly, and further the upper surface of the substrate 9 is dried uniformly and rapidly.

As stated previously, in the substrate processing apparatus 1, dry physical cleaning where liquid is not used is performed to the lower surface of the substrate 9, and the exhaust part 6 for collecting the cleaning drainage on the upper surface of the substrate 9 is provided. Therefore, it is prevented that the cleaning drainage accumulates at the bottom of the chamber 11 to generate mist from the cleaning drainage. Also, because clean air is supplied inside the chamber 11 through a filter(s) provided on the chamber 11, adherence of mist generated from the cleaning drainage or re-adherence of foreign substances to the substrate 9 in the dry process is prevented, and the substrate 9 is dried with maintaining a clean state. After the upper surface of the substrate 9 is dried, the substrate 9 is unloaded from the annular surface 51a of the rotating part 51, and then the cleaning process of the substrate 9 is completed.

As discussed above, in the substrate processing apparatus 1 of FIG. 1, the ring-shaped cover part 61 opposed to the annular surface 51a of the rotating part 51 holding and rotating the substrate 9 is provided, and the exhaust flow space 64 connecting with the gap space 62 between the cover part 61 and the annular surface 51 a along the outer edge of the cover part 61 is formed by the duct main body 63 connected to the cover part 61 along the outer edge of the cover part 61. With this structure, an exhaust duct utilizing the centrifugal force is constructed. Assuming that the cross-sectional area of the exhaust flow space 64 is constant along the rotation direction of the rotating part 51, between the vicinity of the starting point 641 and the vicinity of the opening 642, there arises a big difference in an outlet flow volume of air from the gap space 62 to the outside, and inlet flow speed of air in the gap space 62 varies. In the substrate processing apparatus 1, however, since the cross-sectional area of the exhaust flow space 64 increases gradually along the rotation direction of the rotating part 51, it is possible to reduce variation of inlet flow speed of air around (or across) the gap space 62 and to suppress nonuniformity of the cleaning processing on the upper surface of the substrate 9.

In the substrate processing apparatus 1, by providing the ring-shaped duct, it is possible to reduce the size of the mechanism related to exhausting gas and to downsize the apparatus. And it is possible to downsize the substrate processing apparatus 1 further by using the ring-shaped motor 5. Since the plurality of rectifying plates 611 are provided on the cover part 61 and air in the gap space 62 is guided to the exhaust flow space 64, it is suppressed that turbulent air flow occurs in the gap space 62, and this makes it possible to keep air flow in the gap space 62 stable. In the substrate processing apparatus 1, the upper side surface of the substrate 9 on which the fine pattern is formed is turned up, and cleaning process using cleaning solution may be performed to the upper side surface.

Next discussion will be made on air displacement in the substrate processing apparatus 1, and specific design examples related to the cover part 61, the duct main body 63, and the like will be discussed. FIG. 5 is a view for schematically explaining inlet flow speed of air around (or across) the gap space 62 and FIG. 5 shows the view in a case where the duct main body 63 is not provided. In the following discussion, it is assumed that, when rotation speed of the rotating part 51 reaches a constant speed by driving of the motor 5 and flow of air becomes in the equilibrium state, speed of air thrown out from the outer part of the rotating part 51 toward outside of the rotating part 51 (i.e., outlet flow speed in the outlet cross-section which is the outer side cross-section of the gap space 62) is the same as linear velocity at the outer edge of the rotating part 51 by effects of air viscosity (i.e., so-called drag effects) and that the outlet flow speed is almost constant across the whole outer edge of the rotating part 51. It is also assumed in the following discussion that effects of air compression are ignored, air flows into the gap space 62 in a direction almost perpendicular to the inlet cross-section as shown by the arrow 71 in FIG. 5 and inlet flow speed of air in the gap space 62 approximates outlet flow speed of air from the gap space 62 because of continuity of fluid flow.

Linear velocity v [mm/s] in the outer edge of the rotating part 51 is obtained by (v=π D×A/60) where D is a diameter of the outer edge of the rotating part 51, A [rpm] is a rotation number (per minute) of the motor 5, and π is the circular constant. Also, an amount of air dV flowing (sucked) into the gap space 62 per second from a part in the inlet cross-section corresponding to a minute angle d θ with respect to the central axis 50 is expressed as (dV=Rd θ×H×v) where H [mm] is a height of the gap space 62 (a width in a direction along the central axis 50), and R [mm] is a radius of an inner edge of the cover part 61. A total air displacement V per second from the gap space 62 is equal to an amount of air flowing into the gap space 62 from the whole inlet cross-section and it is obtained by Eq. 1.
V=∫₀^{2π} RHνdθ=2πRHν Eq. 1

In the case where the diameter D of the outer edge of the rotating part 51 is 548 mm, the rotation number A of the motor 5 is 2400 rpm, the height H of the gap space 62 is 10 mm, and the radius R of the inner edge of the cover part 61 is 175 mm, the total air displacement V per minute across the gap space 62 is calculated roughly at 45 m³ by Eq. 1. Although the duct main body 63 is actually provided outside the cover part 61, since the cross-sectional area of the exhaust flow space 64 increases linearly and sufficiently at the rate based on Eq. 1 along the rotation direction, it becomes possible to exhaust air at the above air displacement while suppressing variation of inlet flow speed of air around the gap space 62 without increasing the size of the duct main body 63 unnecessarily. For the duct main body 63 in the embodiment, a width and height of the opening 642 is 100 mm for reasons of design. In this case, the cross-sectional area S [mm²] of the exhaust flow space 64 at a position which is γ [degree] away from the starting point 641 in the rotation direction around the central axis 50 shown in FIG. 2 is obtained by (S=10000×γ/360). A width (or height) K of the cross section of the exhaust flow space 64 at a position which is γ degree away from the starting point 641 in the rotation direction around the central axis 50 is generally expressed as (K=K1+af (γ)) by using a monotonically increasing function f (γ) whose increasing amount decreases according to increase of γ, a predetermined coefficient K1, and a coefficient a (a>0).

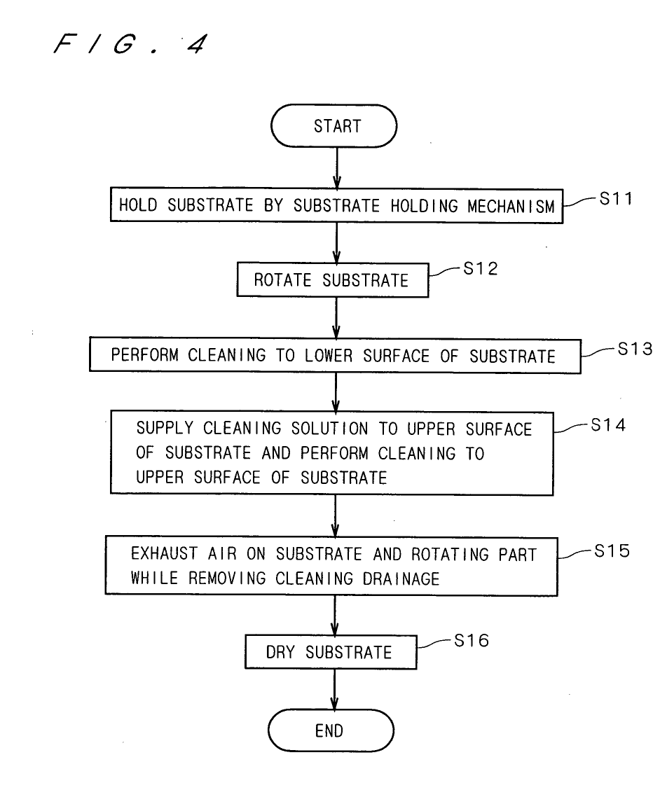

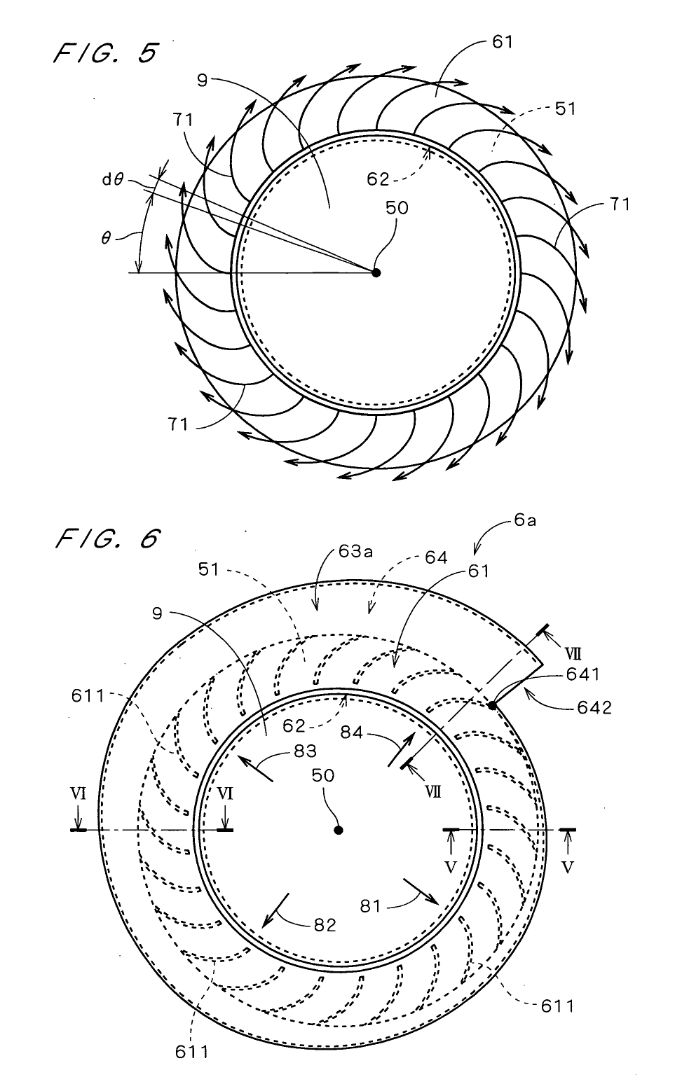

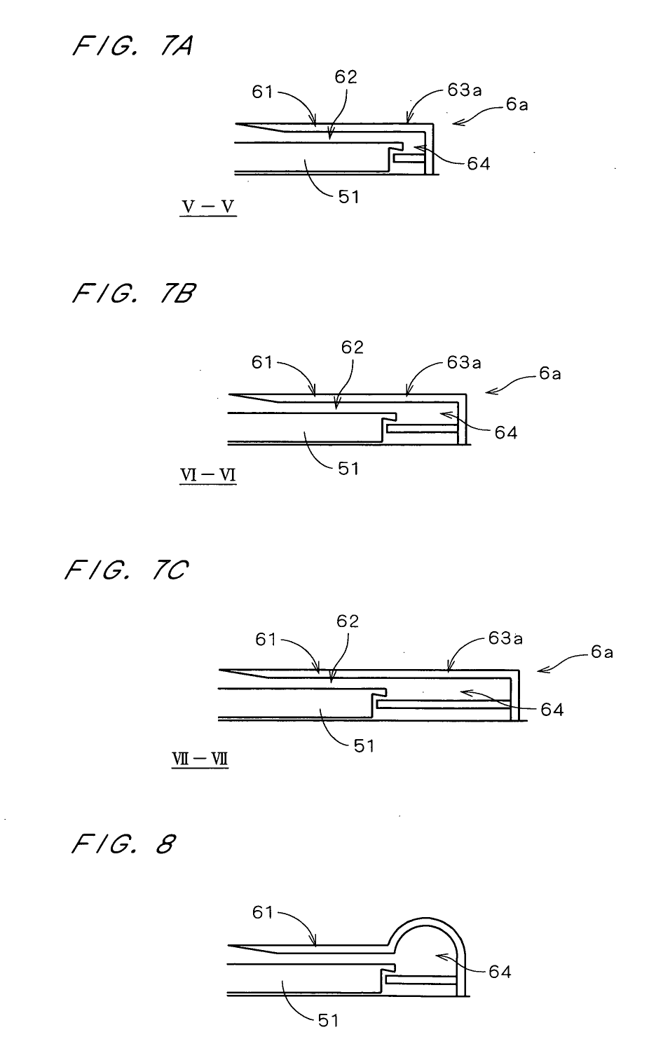

FIG. 6 is a view showing another example of the exhaust flow space. FIGS. 7A to 7C are respectively cross-sectional views at the positions indicated by the arrows V-V, VI-VI, and VII-VII of FIG. 6. In FIGS. 7A to 7C, the rectifying plates 611 and hatching of cross sections are omitted.

In an exhaust part 6a in accordance with another example, a width of a exhaust flow space 64 in the radial direction is very narrow at a position (position corresponding to the position indicated by the arrows I-I in FIG. 2) in the immediate downstream vicinity of a starting point 641 in the rotation direction, like FIG. 3A. In a duct main body 63a, only the width of the exhaust flow space 64 in the radial direction increases gradually in the downstream direction of the rotation. At the position indicated by the arrows V-V of FIG. 6, the width and height of a cross section of the exhaust flow space 64 are the same, as shown in FIG. 7A. Only the width of the exhaust flow space 64 increases gradually from the position indicated by the arrows V-V in the downstream direction of the rotation. As shown in FIG. 7B, the cross section of the exhaust flow space 64 is a horizontally long rectangle at the position indicated by the arrows VI-VI. At the position indicated by the arrows VII-VII in the immediate upstream vicinity of an opening 642 in the rotation direction, only the width of the cross section of the exhaust flow space 64 further increases, as shown in FIG. 7C.

In the substrate processing apparatus 1 with the duct main body 63a, in the case where a rotation number of the motor 5 is 1330 rpm, a height of the gap space 62 is 10 mm, and a radius of the inner edge of the cover part 61 is 175 mm, air flow speed in the opening 642 is 9 m/second by measurement with a hot-wire anemometer. As a cross-sectional area of the opening 642 is 0.001 m², it is confirmed that a total air displacement from the exhaust flow space 64 is 0.54 m³/minute. In this case, inlet flow speeds of the gap space 62 are 2, 2, 1, and 1 m/second at the positions indicated by the arrows 81 to 84 of FIG. 6, respectively, and their average is 1.5 m/second. Since an opening area of the gap space 62 in the inner edge of the cover part 61 (i.e., the opening area is an area of inlet cross-section) is about 0.01 m², an inlet flow volume per minute is about 1 m³. The inlet flow volume of air toward the gap space 62 and the air displacement from the exhaust flow space 64 are approximately balanced (the inlet flow volume of air is less than twice the air displacement).

In view of exhausting air in the exhaust flow space 64 efficiently without loss, it is preferable that a cross section (a cross section in a plane including the central axis 50) of the exhaust flow space 64 has a square shape as shown in FIGS. 3B to 3D, a round shape or a shape (almost semicircle) as shown in FIG. 8. However, according to designs, a heightwise direction is limited in some cases. In the cases, even if a cross section of the exhaust flow space 64 in the duct main body 63a has a flat shape as shown in FIG. 6, by increasing a cross-sectional area of the exhaust flow space 64 in a downstream direction, it is possible to uniform exhausting gas with respect to a circumferential direction roughly.

In view of designing an apparatus easily while decreasing air flow resistance in the exhaust flow space 64, cross-sectional shapes shown in FIGS. 3A to 3D are preferable. In view of decreasing air flow resistance mostly, it is preferable a cross section is round. Also, a cross-sectional shape of the exhaust flow space 64 is not limited to the above examples. In a preferable exhaust flow space, distances from the center of a cross section to respective points on the edge of the cross section are almost same, specifically, any cross section is convex (i.e., any interior angle has a measure less than 180°) and the widest width of any cross section is less than or equal to twice the narrowest width. This makes it possible to suppress variation of inlet flow speed of gas around the gap space 62 further.

Though the preferred embodiment of the present invention has been discussed above, the present invention is not limited to the above-discussed preferred embodiment, but allows various variations.

In the above preferred embodiment, the holding part for holding the substrate 9 is the annular surface 51a and the substrate holding mechanism 2 each of which is a part of the rotating part 51, but the holding part may be provided as a separate member from the motor 5. In the above preferred embodiment, the cover part 61 is provided to be opposed to the annular surface 51a of the rotating part 51. However, for example, in the case of a substrate processing apparatus where the center of the lower surface of the substrate 9 is held by the holding part and the holding part rotates through a shaft of a motor, the cover part 61 may be opposed to the annular zone on the outer part of the rotating substrate 9. In other words, in the substrate processing apparatus, the cover part 61 is opposed to the annular zone on the outer part of the rotating body which includes the holding part and the substrate 9 rotated by the motor 5 and the annular zone is perpendicular to the central axis 50 with its center lying on the central axis 50. It is therefore possible to exhaust gas to the exhaust flow space using the drag effect and the centrifugal force in the annular zone.

The shape of the substrate 9 may be other than disk-shaped, and the substrate 9 may be a printed circuit board, a glass substrate used for a flat panel display apparatus, or the like. For example, when a rectangular plate-like glass substrate is processed in a substrate processing apparatus, a disk-shaped auxiliary member whose size is larger than that of the glass substrate is prepared. The glass substrate is held on the auxiliary member, a cover part opposed to an annular zone on an outer part of the rotated auxiliary member or an annular zone on an outer part of a holding part holding the auxiliary member is provided, and processing the glass substrate is performed.

In the above preferred embodiment, since the inner side surface of the cover part 61 is the inclined surface 610, air and cleaning drainage on the substrate 9 located between the cover part 61 and the annular surface 51a with respect to the central axis 50 direction are sucked into the gap space 62 efficiently. For example, in a case of performing processing such as dry cleaning or the like where liquid is not used, a substrate holding mechanism is provided on an internal side surface of the rotating part 51 and the substrate 9 may be held inside the rotating part 51 with respect to a radial direction and horizontal direction (the substrate 9 is positioned below the annular surface 51a). Also, in this holding method, in the case of performing processing such as wet cleaning or the like where liquid is used, an inclined surface whose diameter gradually increases upward from a position of the upper surface of the substrate 9 is provided on the internal side surface of the rotating part 51, and cleaning drainage on the substrate 9 may be drained into the gap space 62 efficiently.

A rectifying structure for suppressing turbulent air flow in the gap space 62 may be implemented by members except the rectifying plates 611, for example, members whose cross sections are triangle.

In the substrate processing apparatus 1, it is not necessary that only one exhaust flow space is provided along the whole outer edge of the rotating part 51, and a plurality of exhaust flow spaces may be provided along the outer edge of the rotating part 51 without overlapping. In view of decreasing the number of the constituent parts of the substrate processing apparatus 1, however, it is most preferable that only one exhaust flow space is provided along the whole outer edge of the rotating part 51.

To reduce variation of inlet flow speed of air around the gap space 62 still more, it is preferable to make the cross-sectional area of the exhaust flow space increase linearly from the starting point 641 along the rotation direction, but even if the cross-sectional area of the exhaust flow space increases stepwise from the starting point 641 along the rotation direction, it is possible to uniform exhausting roughly.

It is preferable the motor 5 is a hollow motor from the viewpoint of reducing the size of a substrate processing apparatus, but the motor 5 may be other than hollow. For example, as described above, a motor is connected to a disk-shaped holding part through a shaft, and the holding part may hold the center of an lower surface of a substrate. A substrate may be held by a hollow rotating mechanism where a driving mechanism is provided outside separately.

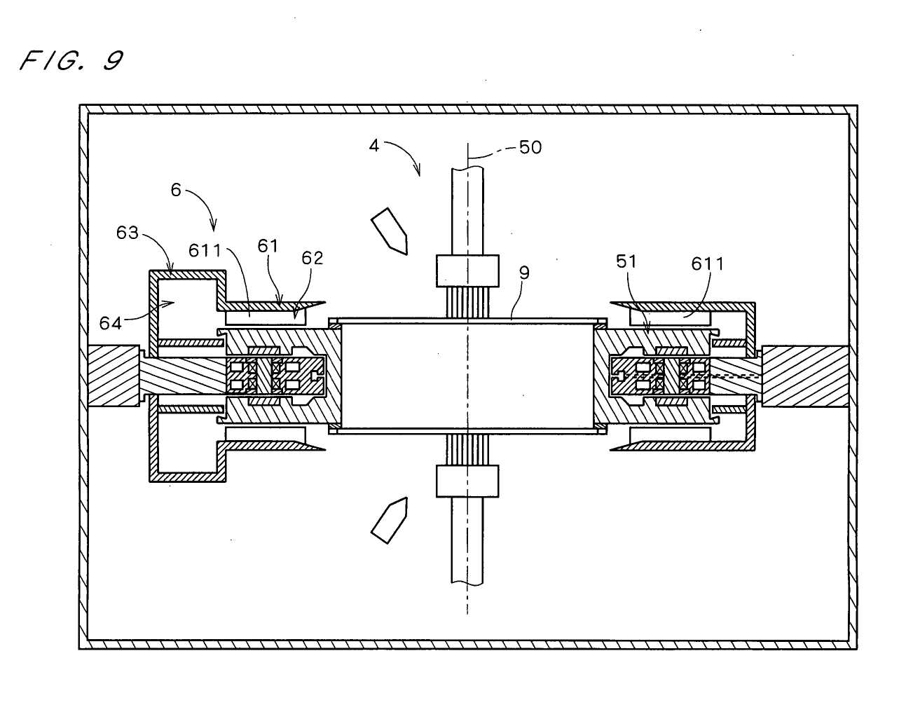

In the above preferred embodiment, the substrate processing apparatus 1 is the apparatus where one substrate 9 is held on the rotating part 51, but the apparatus may have a structure for holding two substrates. As shown in FIG. 9, an additional holding mechanism is provided on the lower surface of the rotating part 51, a substrate on the upper surface of the rotating part 51 is placed with a back side surface turning up, a substrate on the lower surface of the rotating part 51 is placed with a back side surface turning down, and the back side surfaces of both substrates are cleaned with brushes. A ring-shaped cover part opposed to the lower surface of the rotating part 51 is provided, and an exhaust flow space may be formed by a duct main body connected to the cover part. With this structure, it is possible to produce a small apparatus for simultaneously cleaning two substrates.

Though in the above preferred embodiment the substrate processing apparatus 1 is described as a substrate cleaning apparatus for cleaning a substrate, the substrate processing apparatus may be utilized in various applications for processing a substrate by supplying various processing solutions onto a surface of the substrate. Also, the substrate processing apparatus can be utilized in surface treatment, surface fabrication, surface drying, or the like of a substrate where various processing gas or particles are used. Also in the cases, it is possible to exhaust air, processing gas, particles, or the like uniformly and to suppress nonuniformity of processing of the substrate.

While the invention has been shown and described in detail, the foregoing description is in all aspects illustrative and not restrictive. It is therefore understood that numerous modifications and variations can be devised without departing from the scope of the invention.

This application claims priority benefit under 35 U.S.C. Section 119 of Japanese Patent Application No. 2005-54189 filed in the Japan Patent Office on Feb. 28, 2005, the entire disclosure of which is incorporated herein by reference.

What is claimed is:

1. A substrate processing apparatus, comprising:
a holding part for holding a substrate;
a rotation mechanism for rotating said holding part around a predetermined central axis perpendicular to a main surface of a substrate held by said holding part;
a ring-shaped cover part opposed to an annular zone on an outer part of a rotating body which includes said holding part and a substrate rotated by said rotation mechanism, said annular zone being perpendicular to said central axis with a center of said annular zone lying on said central axis; and
a member forming an exhaust flow space which connects with a gap space between said cover part and said annular zone along an outer edge of said cover part, a cross-sectional area of said exhaust flow space increasing along a rotation direction of said holding part.

2. The substrate processing apparatus according to claim 1, wherein
an outer part of said holding part is located outside a substrate held by said holding part and said annular zone lies on said holding part.

3. The substrate processing apparatus according to claim 2, wherein
said holding part is a part of a ring-shaped rotating part combined with a ring-shaped stationary part in a ring-shaped motor, and
said rotation mechanism is a driving mechanism of said motor.

4. The substrate processing apparatus according to claim 3, wherein
a guiding mechanism, for guiding rotation of said ring-shaped rotating part relative to said ring-shaped stationary part, comprises a supplying channel for supplying gas to a clearance between said ring-shaped stationary part and said ring-shaped rotating part,
an auxiliary channel for exhausting gas ejected from said clearance between said ring-shaped stationary part and said ring-shaped rotating part is provided parallel to said exhaust flow space along an outer edge of said motor, and
said exhaust flow space and said auxiliary channel are formed by partitioning a duct provided along said outer edge of said motor.

5. The substrate processing apparatus according to claim 1, wherein
a cross-sectional area of said exhaust flow space at a point on an outer edge of said rotating body is proportional to a distance from a starting point of said exhaust flow space to said point on said outer edge along said outer edge in said rotation direction of said holding part.

6. The substrate processing apparatus according to claim 1, wherein
a width and a height of said exhaust flow space increase gradually along said rotation direction of said holding part.

7. The substrate processing apparatus according to claim 6, wherein
any cross section of said exhaust flow space is convex and the widest width of said any cross section is less than or equal to twice the narrowest width.

8. The substrate processing apparatus according to claim 1, wherein
said cover part comprises a plurality of rectifying structures which project out from a surface opposed to said rotating body and extend from an inner side toward said outer edge of said rotating body with inclining in said rotation direction of said holding part.

9. The substrate processing apparatus according to claim 1, wherein
only one exhaust flow space is provided as said exhaust flow space along whole outer edge of said rotating body.

10. The substrate processing apparatus according to claim 1, further comprising:
a processing solution supplying part for supplying processing solution onto a main surface of a substrate opposed to said cover part, said substrate being held by said holding part, wherein
said main surface of said substrate is located between said cover part and said annular zone with respect to a direction of said central axis and processing solution supplied onto said main surface flows into said exhaust flow space.

11. A substrate processing method, comprising the steps of:
a) holding a substrate by a holding part;
b) rotating said holding part around a predetermined central axis perpendicular to a main surface of said substrate held by said holding part by a rotation mechanism; and
c) exhausting gas from an outer part of a rotating body which includes said holding part and said substrate rotated by said rotation mechanism in parallel with said step b), wherein
in said step c), said gas is exhausted through a gap space and an exhaust flow space, said gap space is formed between an annular zone which is an area on said outer part of said rotating body and a ring-shaped cover part opposed to said annular zone, said annular zone is perpendicular to said central axis with a center of said annular zone lying on said central axis, said exhaust flow space connects with said gap space along an outer edge of said cover part, and a cross-sectional area of said exhaust flow space increases along a rotation direction of said holding part.

12. The substrate processing method according to claim 11, wherein
an outer part of said holding part is located outside a substrate held by said holding part and said annular zone lies on said holding part.

13. The substrate processing method according to claim 12, wherein
said holding part is a part of a ring-shaped rotating part combined with a ring-shaped stationary part in a ring-shaped motor, and
said rotation mechanism is a driving mechanism of said motor.

14. The substrate processing method according to claim 13, wherein
a guiding mechanism, for guiding rotation of said ring-shaped rotating part relative to said ring-shaped stationary part, comprises a supplying channel for supplying gas to a clearance between said ring-shaped stationary part and said ring-shaped rotating part,
an auxiliary channel for exhausting gas ejected from said clearance between said ring-shaped stationary part and said ring-shaped rotating part is provided parallel to said exhaust flow space along an outer edge of said motor, and
said exhaust flow space and said auxiliary channel are formed by partitioning a duct provided along said outer edge of said motor.

15. The substrate processing method according to claim 11, wherein
a cross-sectional area of said exhaust flow space at a point on an outer edge of said rotating body is proportional to a distance from a starting point of said exhaust flow space to said point on said outer edge along said outer edge in said rotation direction of said holding part.

16. The substrate processing method according to claim 11, wherein
a width and a height of said exhaust flow space increase gradually along said rotation direction of said holding part.

17. The substrate processing method according to claim 16, wherein
any cross section of said exhaust flow space is convex and the widest width of said any cross section is less than or equal to twice the narrowest width.

18. The substrate processing method according to claim 11, wherein
said cover part comprises a plurality of rectifying structures which project out from a surface opposed to said rotating body and extend from an inner side toward said outer edge of said rotating body with inclining in said rotation direction of said holding part.

19. The substrate processing method according to claim 11, wherein
only one exhaust flow space is provided as said exhaust flow space along whole outer edge of said rotating body.

20. The substrate processing method according to claim 11, further comprising the step of:
supplying processing solution onto a main surface of a substrate opposed to said cover part in parallel with said step c), said substrate being held by said holding part, wherein
said main surface of said substrate is located between said cover part and said annular zone with respect to a direction of said central axis and processing solution supplied onto said main surface flows into said exhaust flow space.
